(19) United States
(12) Patent Application Publication
(10) Pub. No.: US 2025/0389794 A1
(43) Pub. Date: Dec. 25, 2025

(54) METER AND METHOD PERFORMED BY A METER FOR MEASURING CONDUCTION PATHS OF AN ELECTRICAL MACHINE

(71) Applicant: Megger Instruments Ltd, Dover (GB)

(72) Inventors: Stanislaw ZUREK, Dover (GB); Jeffrey JONES, Dover (GB); Richard WARDAK, Dover (GB); Anthony RIVRON, Dover (GB); Eddie JAKOBITZ, Fort Collins, CO (US); Daniel MELENDY, Fort Collins, CO (US); Daniel ROGGE, Fort Collins, CO (US)

(21) Appl. No.: 18/750,415

(22) Filed: Jun. 21, 2024

(51) Int. Cl. G01R 31/72; G01R 27/16

(52) U.S. Cl. CPC G01R 31/72; G01R 27/16

(57) ABSTRACT

A meter performs measurements of imbalance of an electrical characteristic between conduction paths of an electrical machine having a plurality of stator windings and a rotor, with the rotor in place in the electrical machine. For each of a plurality of conduction paths, each comprising one or more of the plurality of stator windings, the meter provides a test current to the conduction path and performs a measurement A of an electrical parameter of the conduction path in a time window A starting after a delay period from the start of providing the test current and determines a measure of imbalance of the electrical characteristic between the plurality of conduction paths from at least the measurements A of the electrical parameter for the respective conduction paths.

### TECHNICAL FIELD

The present invention relates generally to an improved meter and a method performed by a meter for measuring imbalance of an electrical characteristic between conduction paths of an electrical machine, and more specifically, but not exclusively, to a meter configured to determine impedance imbalance between conduction paths of an electrical machine having a plurality of stator windings and a rotor with the rotor in place in the electrical machine.

### BACKGROUND

An electrical machine, such as a motor or a generator, may comprise a number of stator windings and a rotor, the rotor being inductively coupled to the stator windings. It may be required to test the electrical machine, for example during routine maintenance for early warning of the development of faults which may be potentially dangerous and/or expensive to repair, or for diagnosis of suspected faults. A number of conduction paths may be accessible for testing of the electrical machine, each conduction path comprising one or more of the stator windings. Conventionally, the resistance of a number of conduction paths may be measured, and a degree of imbalance may be calculated between the measured resistance values of the conduction paths. If the resistance of one or more of the conduction paths is outside a predetermined degree of imbalance, for example deviating by more than a certain percentage from a mean value of resistance, then it may be concluded that there may be a fault in the electrical machine and further investigation may be necessary. A meter may be configured to test the imbalance in resistance of the conduction paths, by providing a test current to each conduction path in turn and measuring a voltage across and/or current flowing in each conduction path and calculating the resistance from the ratio of voltage to current. Meters are commercially available to determine automatically the degree of imbalance between the measured resistance of conduction paths of an electrical machine. An imbalance in resistance between the conduction paths may indicate a problem such as a corroded contact or a loose electrical connection.

A test of resistive imbalance may be carried out with the rotor removed from the electrical machine or with the rotor in place in the electrical machine. Typically, tests of resistive imbalance are carried out with the rotor in place, to avoid the time and inconvenience of removing the rotor. Such resistive tests typically measure resistance based on average currents and voltages which are measured while the test current is applied. The results have been found to be useful for detecting faults in the windings of the electrical machine, but the accuracy of the measurements of resistance may be affected by the presence of the rotor. It would be beneficial to be able to perform an improved measurement of imbalance between conduction paths of an electrical machine, with the rotor in place. It would also be beneficial to carry out tests from which further diagnostic information regarding the condition of the electrical machine may be deduced.

### SUMMARY

In accordance with a first aspect of the present invention, there is provided a method performed by a meter for performing measurements of imbalance of an electrical characteristic between conduction paths of an electrical machine having a plurality of stator windings and a rotor, the method comprising, with the rotor in place in the electrical machine: for each of a plurality of conduction paths, each comprising one or more of the plurality of stator windings, providing a test current to the conduction path and performing a measurement A of an electrical parameter of the conduction path in a time window A starting after a delay period from the start of providing the test current; and determining a measure of imbalance of the electrical characteristic between the plurality of conduction paths from at least the measurements A of the electrical parameter for the respective conduction paths.

Performing the measurement of the electrical parameter of the conduction path in a time window starting after a delay period from the start of providing the test current has been found by the inventors to allow the measurements in the time window to be made without being influenced by a combination of resistive and induced voltage effects. It has been found that currents and voltages measured in the conduction paths through the stator may be affected by voltages induced in the rotor, which are due to a change in the test current applied to the stator. After the delay period, the effects of resistive and/or induced voltage effects may be measured separately. In a first case, in which the test current is provided during the time window for the measurements, a measure of imbalance of resistance may be made after the delay period with reduced effects from induced voltages, which were initially induced when the test current was turned on. In a second case, in which the test current is stopped before the time window for measurements, a measure of induced voltage may be made with reduced resistive effects, because the test current is not flowing during the time window, and so a voltage is not generated by the test current flowing through the conductive path.

In an example, the delay period is at least as long as the time window A. This has been found to provide a beneficial compromise between the time taken for the test and the separation of resistive and induced voltage effects.

In an example, the delay period is sufficient to allow the electrical parameter of the conduction path to settle to within 10% or less of a steady state value. For example, the electrical parameter may be voltage and/or current.

In an example, the method comprises providing the test current to the conduction path for at least the delay period and the time window A. This allows a measurement of impedance to be made in the time window A on the basis of a value of the test current and a measured voltage, as in the case mentioned above.

In an example, the electrical characteristic is impedance and the method comprises: for each of the plurality of conduction paths, performing a measurement B of the electrical parameter of the conduction path in a time window B which starts before the time window A; calculating a measure A of the impedance for each conduction path from the measurement A of the electrical parameter; calculating a measure B of the impedance for each conduction path from the measurement B of the electrical parameter; performing a correction of the measure B of the impedance for each conduction path using the measure A of the impedance for the respective conduction path; and determining a dynamic measure of impedance imbalance, the dynamic measure of impedance imbalance being the imbalance of the corrected measures B for the plurality of conduction paths and determining a static measure of impedance imbalance, the static measure of impedance imbalance being the imbalance of the measures A for the plurality of conduction paths.

This allows static and dynamic measures of impedance imbalance to be determined. The static measure represents pure resistive impedance imbalance, generated without effects of induced voltage, because the induced voltages caused by the start of the test current have been allowed to decay in the delay period. The dynamic measure of impedance imbalance has been corrected by removing effects of resistive imbalance. As a result, there are two measures which represent different characteristics of the electrical machine, which may be used to diagnose specific faults in the electrical machine. The static measure of imbalance may be used to identify faults of a resistive nature, such as corroded or loose contacts or damaged conductors. The dynamic measure of imbalance may be used to identify faults of an electromagnetic nature, such as a fault in any of the electromagnetic components of the motor (stator winding, stator core, rotor winding, rotor core, air gap between the stator and rotor core). A conventional approach, using a measure of impedance imbalance which is measured from when the test current is initially turned on, without a correction for the static (resistive) imbalance, cannot distinguish between resistive and electromagnetic causes of imbalance.

In an example, performing the correction of the measure B for each conduction path comprises subtracting the difference between measure A and the mean of measures A for the plurality of conduction paths from measure B for the respective conduction path. This allows the contribution to dynamic imbalance from an imbalance due to resistive effects to be removed.

In an example, performing the correction of the measure B for each conduction path comprises quadrature processing of the measure B and the measure A for the respective conduction path. This allows more accurate correction of dynamic imbalance when the dynamic imbalance is large.

In an example, the time window A for each of the plurality of conduction paths occurs after a waiting time after the end of the time window B. This provides for an initial time window, window B, intended to capture the dynamic effects after the test current is turned on, followed by a waiting time to allow for further settling of the dynamic effects, followed by the time window A, in which the resistive imbalance can be evaluated. In the waiting time, both static and dynamic imbalance effects may be present together and may be difficult to separate.

In an example, the method comprises performing the measurement B of the electrical parameter a plurality of times for each of the plurality of conduction paths and determining a plurality of dynamic measures of impedance imbalance from the measurements B. This allows for information to be extracted about the conduction path which decays more quickly or more slowly in terms of magnitude of imbalance than the others. This may enable further diagnosis of a potential fault to be carried out.

In an example, the method comprises determining a measure of the variation of the plurality of the dynamic measures of impedance imbalance and performing further measurements B dependent on the measure of the variation exceeding or equalling a threshold. This allows further tests to be performed to reduce the uncertainty of the measures of impedance imbalance.

In an example, the method comprises generating an indication of a first type of fault in the electrical machine dependent on a determination that the dynamic measure of impedance imbalance exceeds a threshold. The first type of fault may comprise a fault in an electromagnetic component of the machine.

In an example, the method comprises generating an indication of a second type of fault in the electrical machine dependent on a determination that the static measure of impedance imbalance exceeds a threshold. The second type of fault may comprise a fault causing a change in resistance.

In an example, the method comprises stopping providing the test current after the time window A, and for each of the plurality of conduction paths, performing a measurement C of an electrical parameter across the conduction path in a time window C starting after stopping providing the test current; and determining a measure of imbalance of induced voltage characteristics between the plurality of conduction paths from at least the measurements C of the electrical parameter for the respective conduction paths. This allows a third measure of imbalance to be determined, in addition to the static and/or dynamic balance. Stopping the test current induces a voltage in the rotor and causes a current to flow in the rotor, which in turn induces a voltage in the stator. The measure of imbalance of induced voltages in the conduction paths provides a further indication of an electromagnetic fault, which inherently has resistive effects reduced, due to the lack of test current flowing in the stator. This may be used for further diagnosis of faults in electromagnetic components.

In an alternative approach, the test current may be stopped before the time window A, as in the second case mentioned above. In this case, a measure of imbalance of induced voltages is determined from measurements of induced voltage in time window A, instead of determining the measure of static imbalance in this time window. The measure of imbalance of induced voltages may be used for diagnosis of faults in electromagnetic components instead of the previously mentioned measure of dynamic imbalance. In an example, an indication of a fault in an electromagnetic component in the electrical machine may be generated dependent on a determination that the imbalance of induced voltage characteristics exceeds a threshold.

In accordance with a second aspect of the invention, there is provided a meter for performing measurements of imbalance of an electrical characteristic between conduction paths of an electrical machine having a plurality of stator windings and a rotor with the rotor in place in the electrical machine, the meter comprising a current generation circuit, an electrical parameter measurement circuit, one or more processors and memory holding computer-readable instructions configured to cause the one or more processors to cause the meter to perform a method comprising:
for each of a plurality of conduction paths, each comprising one or more of the plurality of stator windings providing a test current to the conduction path and performing a measurement A of an electrical parameter of the conduction path in a time window A starting after a delay period from the start of providing the test current; and
determining a measure of imbalance of the electrical characteristic between the plurality of conduction paths from at least the measurements A of the electrical parameter for the respective conduction paths.

In an example, the meter comprises a switch matrix configured, under control of the one or more processors of the meter, to connect a current generation circuit and an electrical parameter measurement circuit to each of a plurality of windings of the electrical machine in turn for tests of the respective winding.

Further features and advantages of the invention will be apparent from the following description of exemplary embodiments of the invention, which are given by way of example only.

### BRIEF DESCRIPTION OF THE DRAWINGS

FIG. 1 is a schematic diagram illustrating an example of a meter for performing measurements of imbalance of an electrical characteristic between conduction paths of an electrical machine, the meter having a switch matrix connecting a measurement circuit to the electrical machine;

FIG. 2 is a schematic diagram illustrating a further example of a meter for performing measurements of imbalance of an electrical characteristic between conduction paths of an electrical machine, the meter having a switch matrix connecting the meter to the electrical machine;

FIG. 3a is a schematic diagram illustrating conduction paths through windings of a three-phase stator connected in a delta configuration;

FIG. 3b is a schematic diagram illustrating conduction paths through windings of a three-phase stator connected in a star configuration;

FIG. 4 illustrates an electrical machine, in this case a motor, connected by a cable to a motor control centre, showing that terminals 1, 2 and 3 for connection to the electrical machine may be located at the motor control centre;

FIG. 5 is a schematic diagram illustrating a representation of a stator winding and a rotor of the electrical machine in terms of equivalent electrical circuit components;

FIG. 6 illustrates, as a function of time, the current in the stator, the current in the rotor, the voltage across the stator and the voltage across the rotor during and after the provision of a test current to the stator;

FIG. 7 illustrates examples of time windows A, B and C and the delay period in relation to time periods T1, T2, T3 and T4 as shown in FIG. 6;

FIG. 8 is a graph plotting an electrical parameter of each conduction path, in this case impedance, as a function of time, showing two time windows for measurements of impedance imbalance;

FIG. 9 shows sections of the two time windows shown in FIG. 8 in more detail;

FIG. 10 is a graphical illustration of the use of static measure of impedance imbalance measured in a second time window for correction of a dynamic measure of impedance imbalance measured in a first time window; and

FIG. 11 is a flow diagram of a method of operation of a meter for performing measurements of imbalance of an electrical characteristic between conduction paths of an electrical machine having a plurality of stator windings and a rotor according to this disclosure.

### DETAILED DESCRIPTION

By way of example, embodiments of the invention will now be described in the context of a meter for testing imbalance of one or more electrical characteristics of an electrical machine, with the example the electrical machine being a three-phase motor being described. However, it will be understood that embodiments of the invention may relate to testing of other electrical machines, such as generators, and that embodiments of the invention are not restricted to testing of three phase machines and may relate to testing of imbalance between any number of conduction paths.

As mentioned in the Background section, conventional tests of resistive imbalance between conduction paths of electrical machines such as motors are carried out by applying a test current to each conduction path in turn, and determining resistance by measuring average voltage and current values for the period that the test current is applied. The results have been found to be useful for detecting faults in the windings of the electrical machine, but the accuracy of the measurements of resistance may be affected by the presence of the rotor.

According to the current disclosure, it has been found that currents and voltages measured in the conduction paths through the stator of an electrical machine may be affected by voltages induced in the rotor, which are due to a change in the test current applied to the stator. As a result, conventional measurements of resistive balance, carried out with the rotor in place, are influenced by a combination of resistive and induced voltage effects. This makes it difficult to diagnose problems with the electrical machine, because the test cannot distinguish between purely resistive and electromagnetic effects, each of which may be caused by a different fault.

The inventors have found that providing a delay period from the start of providing the test current allows the measurements to be made without being influenced by a combination of resistive and induced voltage effects. After the delay period, the effects of resistive and/or induced voltage effects may be measured separately. In a first case, in which the test current is provided during the time window for the measurements, a measure of imbalance of resistance may be made after the delay period with reduced effects from induced voltages, which were initially induced when the test current was turned on. In a second case, in which the test current is stopped before the time window for measurements, a measure imbalance of induced voltage may be made with reduced resistive effects, because the test current is not flowing during the time window, and so a voltage is not generated by the test current flowing through the conductive path.

Furthermore, the inventors have found that the results of resistive imbalance measured after the delay period may be used to correct measurements of impedance imbalance measured in an initial period after the application of the test current. This correction may remove or reduce the effects of resistive imbalance, leaving predominantly the effects of imbalance caused by differences in induced voltage in the rotor. As a result, two measures of imbalance may be generated, which can be used to diagnose different faults in the electrical machine. The resistive imbalance, which may be referred to as static imbalance, may be used to diagnose resistive faults in the stators or connecting cables, such as corroded connectors, loose bolts or damaged conductors. The corrected impedance imbalance measured in the initial period after application of the test current, which may be referred to as dynamic imbalance, may be used to diagnose electromagnetic faults, such as faulty gaps in the magnetic circuit between the stator and the rotor, as well as faults in the rotor.

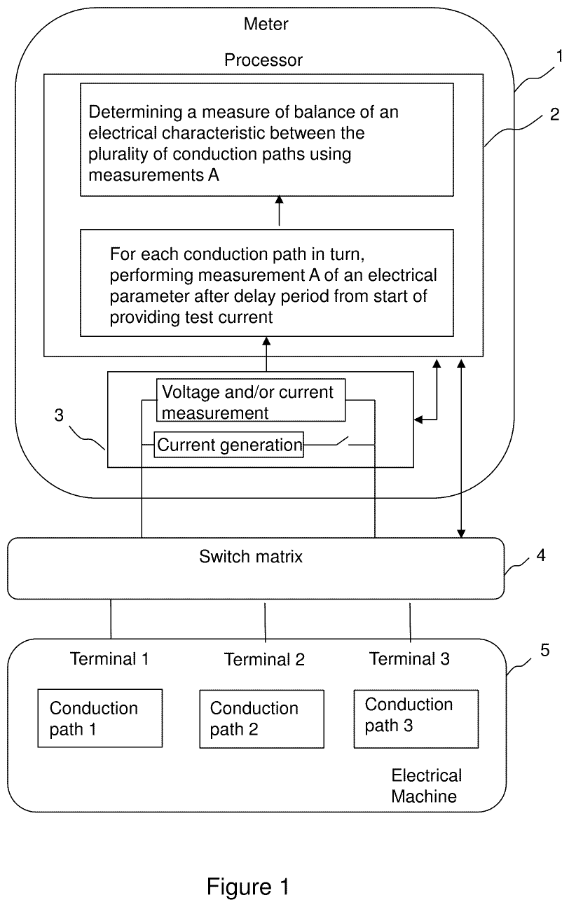

FIG. 1 shows an example of a meter 1 for performing measurements of imbalance of an electrical characteristic between conduction paths of an electrical machine 5, the meter having a switch matrix 4 connecting a measurement circuit 3 to the electrical machine. The meter has a processor 2, which may be implemented, for example, in firmware, such as a gate array, and/or as a microprocessor having memory holding computer-readable instructions, or as remote cloud processing connected to the meter by a data link. The processor causes the meter to perform measurements of imbalance of an electrical characteristic between the conduction paths, in this case conduction paths 1, 2 and 3, of the electrical machine 5. The electrical machine 5 has a plurality of stator windings and a rotor, the rotor being in place during the test of imbalance. Each conduction path comprises one or more of the plurality of stator windings. For each of the plurality of conduction paths, the processor 2 causes the current generation circuit to provide a test current to the conduction path. In an example, the test current may be provided as a constant current, and the current and/or voltage across the conduction path may be measured to determine the impedance of the path. Alternatively, a constant voltage may be provided, and again the current and/or voltage across the conduction path may be measured to determine the impedance of the path. The processor 2 causes the switch matrix 4 to connect the appropriate conduction path to the measurement circuit 3 in turn. For each conduction path, the measurement circuit performs a measurement A of an electrical parameter of the conduction path in a time window A starting after a delay period from the start of providing the test current. The electrical parameter may be impedance, and/or current and/or voltage. The term impedance is used as a broad term to include resistance and may also include reactive components caused by electromagnetic effects. The processor 2 then determines a measure of imbalance of the electrical characteristic, such as impedance or induced voltage, between the plurality of conduction paths from at least the measurements A of the electrical parameter for the respective conduction paths. The meter may display the determined measures of imbalance and may display a suggested diagnosis of a fault if one or more imbalances exceeds a respective threshold value, for example 1%.

The switch matrix 4 may be incorporated into the same enclosure as the processor 2 and measurement circuit 3 of the meter or may be provided as an external component connected by appropriate leads to the enclosure of the processor 2 and measurement circuit 3 of the meter 1 as shown.

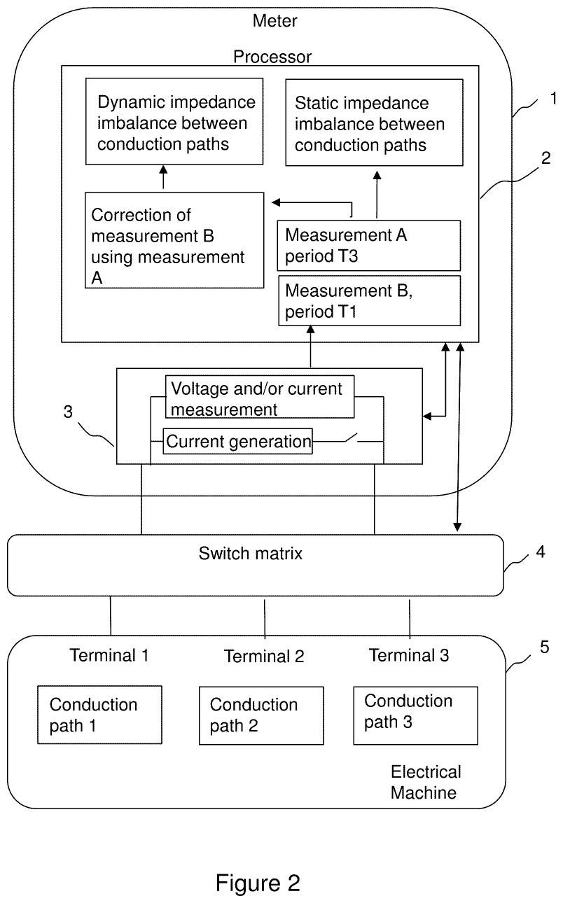

FIG. 2 shows a further example of a meter in which the processor 2 is configured to cause the current generation circuit to provide the test current to each conduction path for at least the delay period and the time window A. This allows a measurement of impedance to be made in the time window A on the basis of a value of the test current and a measured voltage. For each of the plurality of conduction paths, a measurement B is performed of the electrical parameter, which may be impedance and/or voltage and current, of the conduction path in a time window B which starts before the time window A. The measurements may comprise an average of samples taken during the time window for the respective parameter. This time window B may be the initial time window when the test current is started. A measure A is calculated of the impedance for each conduction path from the measurement A of the electrical parameter, and a measure B of the impedance for each conduction path is calculated from the measurement B of the electrical parameter. A correction is performed of the measure B of the impedance for each conduction path using the measure A of the impedance for the respective conduction path. A dynamic measure of impedance imbalance is determined, the dynamic measure of impedance imbalance being the imbalance of the corrected measures B for the plurality of conduction paths. The dynamic measure of impedance imbalance has been corrected by removing effects of resistive imbalance. A static measure of impedance imbalance is also determined, the static measure of impedance imbalance being the imbalance of the measures A for the plurality of conduction paths. The static measure represents pure resistive impedance imbalance, generated without effects of induced voltage, because the induced voltages caused by the start of the test current have been allowed to decay in the delay period.

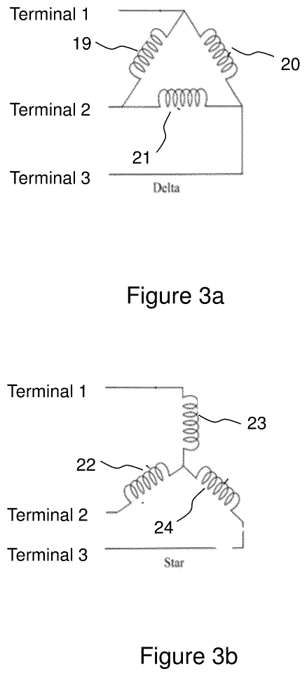

FIG. 3a is a schematic diagram illustrating conduction paths through windings of a three-phase stator connected in a delta configuration. It can be seen that the conduction path between terminal 1 and terminal 3 comprises winding 20 in parallel with the series combination of winding 21 and winding 19. The conduction path between terminal 1 and terminal 2 comprises winding 19 in parallel with the series combination of winding 21 and winding 20 and the conduction paths between terminal 2 and terminal 3 comprises winding 21 in parallel with the series combination of winding 19 and winding 20.

FIG. 3b is a schematic diagram illustrating conduction paths through windings of a three-phase stator connected in a star configuration. It can be seen that the conduction path between terminal 1 and terminal 2 comprises winding 23 in series with winding 22. The conduction path between terminal 1 and terminal 3 comprises winding 23 in series with winding 24 and the conduction path between terminal 2 and terminal 3 comprises winding 22 in series with winding 24.

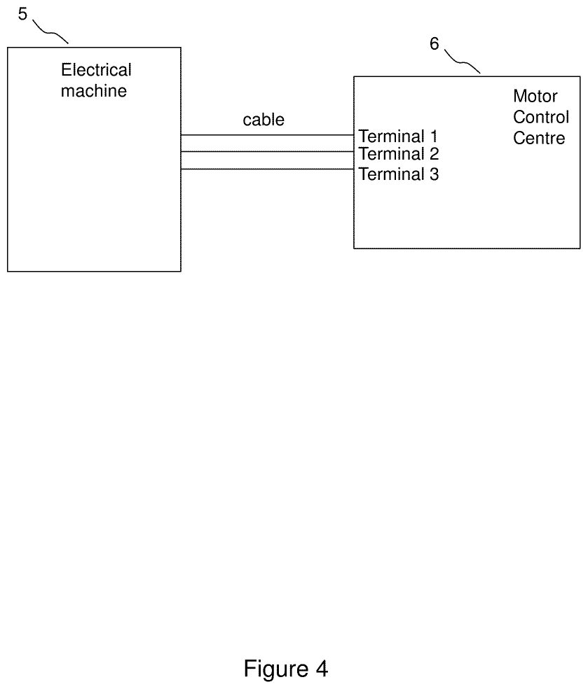

FIG. 4 illustrates an electrical machine 5, in this case a motor, connected by a cable to a motor control centre 6, showing that terminals 1, 2 and 3 for connection to the electrical machine may be located at the motor control centre.

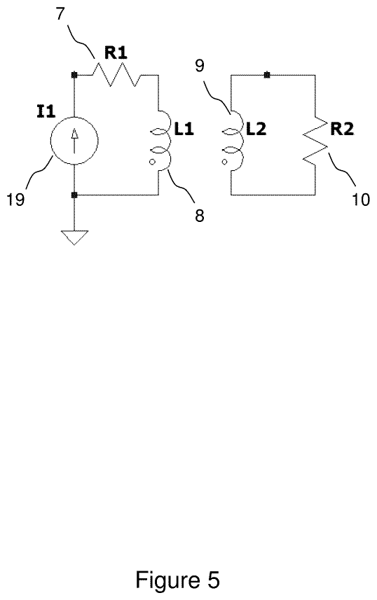

FIG. 5 shows a stator winding 7, 8 and a rotor 9, 10 of the electrical machine 5 in terms of equivalent electrical circuit components. The stator winding may be seen as having a resistance R1 7 in series with an inductance L1 8. The rotor may be seen as having a resistance R2 10 in series with an inductance L2 9. A test current I1 19 is applied to the rotor winding, as part of a conduction path. The rotor is inductively coupled to the stator winding by mutual inductance between L1 8 and L2 9. Accordingly, L1 and R1 represent the stator, specifically the windings which are under test for the specific part (e.g. between phase 1-phase 2). The current source I1 represents the test current. The rotor is electrically floating and has the main components of L2, R2. Any change of current in the stator is transformed (via the effective L1-L2 transformer) to the rotor. When the stator current is switched off, which also represents a step change, a current of opposite polarity is induced in the rotor, and the voltage induced in L1 due to current in L2 is measurable on the stator terminals.

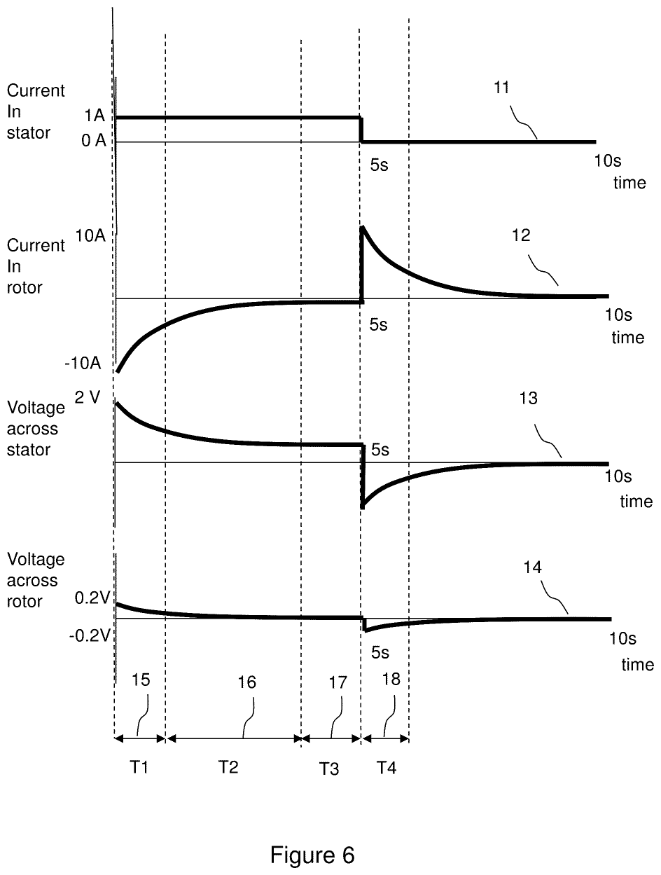

FIG. 6 illustrates, as a function of time, curves showing the current 11 in the stator, the current 12 in the rotor, the voltage 13 across the stator and the voltage 14 across the rotor during and after the provision of a test current to the stator. At the beginning of trace 11, at 0 seconds, the test current is started. In this example, the test current is applied for 5 seconds and then stopped. The timings shown are examples only, and other timings are possible. The shapes of the curves are illustrative only and specific examples may differ. It can be seen from curve 12 that a current is induced in the rotor when the current in the stator turns on, and an opposite current is induced when the current turns off. It can be seen from curve 13 that the voltage across the stator initially peaks when the current turns on, and then decays towards a steady state, representing, in the steady state, the voltage across the resistance of the stator caused by the test current. When the test current turns off, an opposite polarity voltage is induced in the stator to that induced when the current turned on, which then decays towards zero because no test current is present. The voltage across the stator is induced due to the current in the rotor. Curve 14 shows the voltage across the rotor; this is typically smaller than the voltage across the stator since the rotor has relatively low impedance and less effective turns, to the extent that it acts as a transformer with the winding of the rotor.

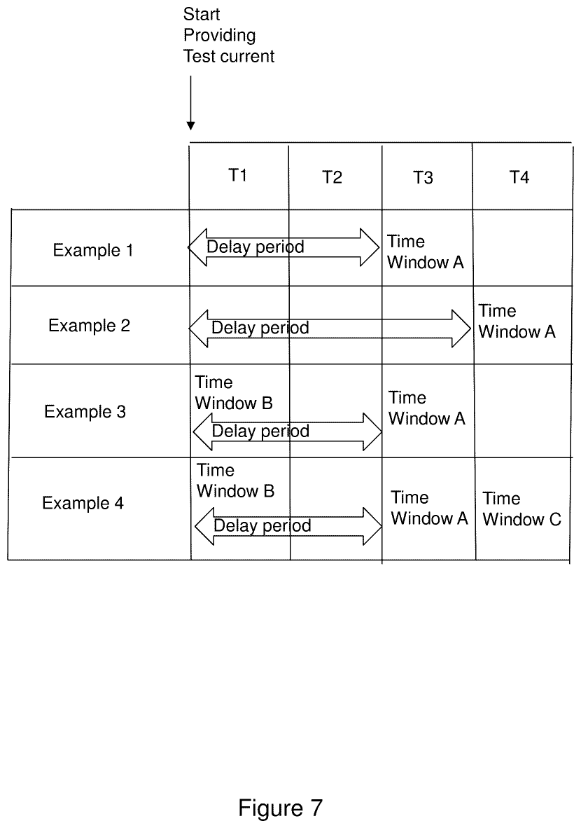

In FIG. 6, time periods T1 15, T2 16, T3 17 and T4 18 are indicated, which are referred to in FIG. 7. FIG. 7 illustrates examples of time windows A, B and C and the delay period in relation to time periods T1, T2, T3 and T4 as shown in FIG. 6. In example 1, time window A is used to determine static balance, in period T3 of FIG. 6. This is after a delay period corresponding to time periods T1 and T2. It can be seen from FIG. 6 that the voltage across the stator is relatively constant in period T3 and represents the voltage due to the test current flowing through the resistance of the stator. Therefore, in window A an accurate measure of resistive imbalance, the static imbalance, may be measured.

Moving to example 3, time window A in time period T3 is again used to measure static imbalance, but in addition a measure of dynamic imbalance is made in time window B in time period T1. In time period T1, the effects of induced voltage are pronounced. The dynamic imbalance is corrected to remove the effects of resistive imbalance, using the static imbalance measurements.

In example 4, the static and dynamic balance are calculated as in examples 1 and 2, but in addition, a third measure of imbalance is calculated based on measurements of induced voltage made in time window C, corresponding to period T4 after the test current has stopped. It can be seen that in time window C, the induced voltage is present in the stator winding, but there is no voltage due to the test current. As a result, imbalance due to resistive effects are absent or small, and an imbalance in induced voltage may give a useful diagnostic tool to diagnose faults exhibiting electromagnetic effects, such as faults in the rotor or in coupling to the rotor. The imbalance in the induced voltage represents mostly effects in the rotor, but as seen through the stator windings. This does not guarantee that rotor-only defects will be detected, but the influence of R1 can be avoided because there is no current (or insignificant) flowing in the stator, so there is no need for correcting for voltage drop across R1 (and other resistance components such as connections).

In an example, the measurement of induced voltage and induced voltage imbalance could be replaced with a current measurement, and current imbalance may be calculated from this, by shorting the input to ground, and measuring the resulting current which will be reflected from the rotor.

Turning now to example 2, in this case the time window A falls in time period T4, after the test current has stopped. The measurements of induced voltage and the calculation of imbalance in induced voltage are the same as those that have been described in time window 4 in example 4, except that the static and dynamic impedance balance need not be determined. The imbalance in induced voltage may be used as a diagnostic tool on its own.

In an example, performing the correction of the measure B for each conduction path comprises subtracting the difference between measure A and the mean of measures A for the plurality of conduction paths from measure B for the respective conduction path. Alternatively, performing the correction of the measure B for each conduction path comprises quadrature processing of the measure B and the measure A for the respective conduction path, allowing more accurate correction of dynamic imbalance when the dynamic imbalance is large.

In other examples, the measurement B of the electrical parameter, typically the impedance, may be performed several times for each of the plurality of conduction paths and determining several dynamic measures of impedance imbalance may be determined from the measurements B. This allows for information to be extracted about the conduction path which decays more quickly or more slowly in terms of magnitude of imbalance than the others. This may enable further diagnosis of a potential fault to be carried out. Further measurements B may be performed dependent on a measure of variation between successive measurements exceeding or equalling a threshold. This allows further tests to be performed to reduce the uncertainty of the measures of impedance imbalance.

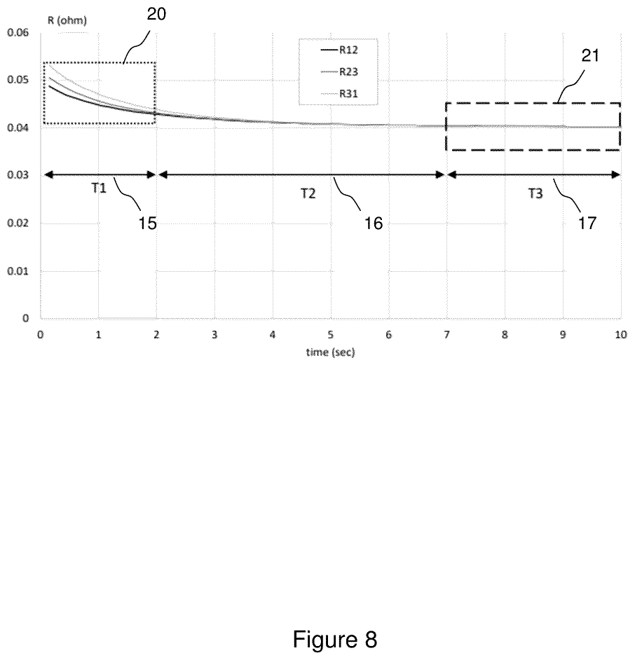

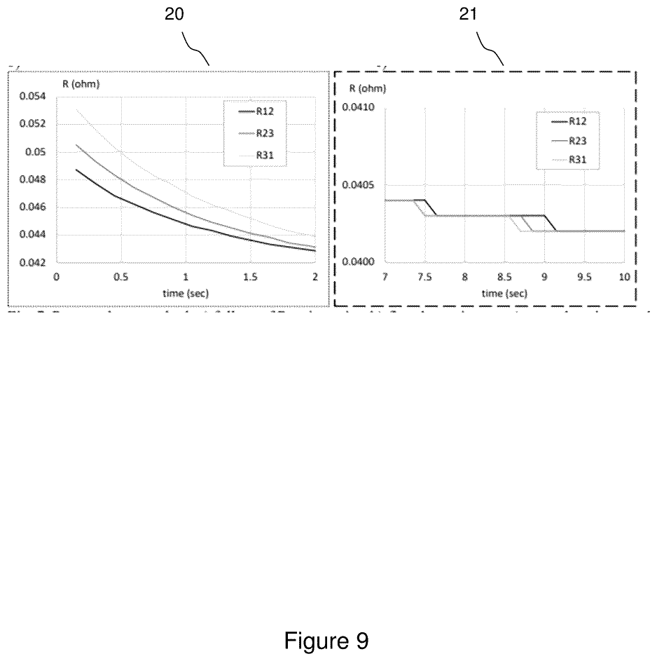

Conventional tests of resistive imbalance in motors are carried out in the period T1 shown schematically in FIG. 6. This is because multiple tests need to be performed, and time may be limited. Typically, a conventional test of resistive imbalance may be carried out from the beginning of application of a test current for about 2 seconds. Although the test may be termed “resistive imbalance”, it can be seen from the present disclosure that in fact the conventional test measures a conflation of resistive and induced voltage imbalance. The test current is typically stopped after the measurements have been taken, i.e. after about 2 seconds. By contrast, according to this disclosure, the test current may be applied for the full duration required to achieve steady state to a satisfactory level. The analysis of the test data is then purposefully split into at least two windows, which signify different properties of the motor under test, as illustrated by FIG. 8 and FIG. 9.

FIG. 8 is a graph plotting an electrical parameter of each conduction path, in this case impedance R12, R23 and R31, as a function of time, showing two time windows 20, 21 for measurements of impedance imbalance and FIG. 9 shows sections of the two time windows 20, 21 shown in FIG. 8 in more detail. Respective measurements of impedance R12, R23 and R31 are shown for the plurality of conduction paths as a function of time. The time intervals T1 15, T2 16 and T3 17 are shown in FIG. 8. T1 corresponds to time window B and T2 corresponds to time window A in this example.

The initial part of the fast-changing data is used for determination of the dynamic properties of the whole stator-rotor system, which includes windings and cores in both parts (stator and rotor). A local fault in any of the electromagnetic components of the motor (stator winding, stator core, rotor winding, rotor core, air gap between the stator and rotor core) will manifest itself in this initial part of the curves and thus a first “resistive” or dynamic imbalance value (including also the effects of induced voltage) can be calculated for this window (dotted rectangle 20 in FIG. 8), and in this case it was R dyn %=3.5%.

Each curve in FIG. 8 is measured by applying and holding the test current for a time which is long enough to reach a satisfactory steady state and to make measurement after that. In the case shown in FIG. 8 this was 10 sec, but for larger motors it can be even more than that. For example, as can be seen in the second graph of FIG. 9, the traces are still decaying (albeit very little) even after 8 sec, so ideally, the waiting time should be even longer. In practice, the changes are already less than 0.001Ω which would be sufficient for termination of the test current, because this could be below the resolution of the tester.

For the second window shown in FIGS. 8 and 9 (dashed rectangle 21) the second resistive or static imbalance value can be calculated. It should be noted that this second value represents true DC resistance of the whole tested electrical circuit only (i.e. motor windings, connections, cable if tested remotely from the Motor Control Centre, etc.) and thus problems with connections or corrosion can be easily identified. In the case of FIG. 9, the value was R stat %=0.02% indicating extremely good balance of the copper connections.

It should be noted that if only the first window is used for fault identification (as is done ordinarily in currently used testers) then this does not allow inference of the static state of the connections, because they can be easily overshadowed by the dynamic processes. By the presently disclosed approach, an improved diagnostics capability is achieved because bad connections can be easily discerned from the same test, separately or in addition to the problems indicated by the dynamic part. Moreover, it is also possible to exclude the core and rotor faults because these would be purposefully ignored in the Rstat % assessment. For example, if both imbalance values (dynamic Rdyn %, and static Rstat %) show high numbers then it is likely that only copper connection contributes to the problem. This could not be discerned through the ordinary imbalance tests. In the presently disclosed method, more accurate diagnostics can be provided before the motor is disassembled, which is obviously highly advantageous.

In a first example, let us assume a situation in which there are two separate faults. One is such that the dynamic processes are in general similar as in FIG. 9 but such that the R12 and R23 (the impedances between the first terminal and second terminal, and the second terminal and the third terminal respectively) report lower values than R31, by around 3%. At the same time, there is a connection problem with just the terminal no. 2 so that it has its resistance higher by around 3% than the other two terminals. This additional DC resistance in no.2 will show up in both R12 and R23 measurements and will make the values proportionally higher even in the dynamic test. Therefore, the calculated R dyn % would apparently become a smaller number and the analysis based just on the short initial test would indicate that there is no problem at all, whereas in fact there are two problems which mask each other so that no reliable fault analysis can be made from just the initial part (as it would be used by an ordinary test).

However, in the same example, if we measure both coefficients R dyn % and R stat % (with the correction by the algorithm) then we can detect that R dyn %=3% but R stat %=3%, clearly indicating a serious problem with both the metallic connections (if the pass/fail threshold value was 1%) as well as with the magnetic structure of the motor.

It is possible to infer from the calculations for the R stat % value which phase is the outlier producing the maximum value. The R dyn % calculations can be corrected by appropriately subtracting the offset resulting from the R stat % value (either in a linear way, or in quadrature, as applicable). The corrected R dyn corr % value can be then used to infer the presence of fault in all the contributing electromagnetic components (as a group: stator, rotor, windings, core, air gap).

Table 1 shows an example (a) in which the raw dynamic imbalance is R dyn raw %=3.3% which would typically indicate a serious problem because the value is significantly above 1% threshold for an acceptable imbalance. In this example R dyn raw % is synonymous with the ordinary test as carried out now.

TABLE 1
Example of the double imbalance test algorithm (where i and j denote 1-2-3 as required.
(a) Dynamic part, initial calculation

| | | % differences | |
|---|---|---|---|
| | | (Rij dyn − Ravg raw)/ | dynamic imbalance |
| raw measured values | average | Ravg raw * 100 | (max of abs(diff)) |
| R12 dyn raw = 122 mΩ | Ravg dyn | dR12 dyn raw = 1.7% | R dyn raw % = |
| R23 dyn raw = 121 mΩ | raw = | dR23 dyn raw = 1.7% | 3.3% |
| R31 dyn raw = 117 mΩ | 120 mΩ | dR31 dyn raw = −3.3% | |

(b) Static part ohmic

| Measured values | Average | ohmic differences (to be used for correction) |
|---|---|---|
| R12 stat = 102 mΩ | Ravg stat = | dR12 stat ohm = R12 stat − Ravg stat = 2 mΩ |
| R23 stat = 102 mΩ | 100 mΩ | dR23 stat ohm = R23 stat − Ravg stat = 2 mΩ |
| R31 stat = 96 mΩ | | dR31 stat ohm = R31 stat − Ravg stat = −4 mΩ |

(c) Static part, percentage

| | | % differences | imbalance (max |
|---|---|---|---|
| Measured values | Average | (dRij stat ohm/Ravg stat) * 100 | of abs(diff)) |
| R12 stat = 102 mΩ | Ravg stat = | dR12 stat % = 2% | R stat % = 4% |
| R23 stat = 102 mΩ | 100 mΩ | dR23 stat % = 2% | |
| R31 stat = 96 mΩ | | dR31 stat % = −4% | |

(d) Dynamic part, corrected

| corrected values | | % differences | |
|---|---|---|---|
| Rij dyn corr = Rij | average | (Rij dyn corr − Ravg dyn corr)/ | dynamic imbalance |
| dyn raw − Rij stat ohm | corr | Ravg dyn corr * 100 | (max of abs(diff)) |
| 122 mΩ − 2 mΩ = 120 mΩ | Ravg dyn | dR12 dyn corr % = 0.0% | R dyn corr |
| 121 mΩ − 2 mΩ = 119 mΩ | corr = | dR23 dyn corr % = −0.8% | % = 0.8% |
| 117 mΩ − −4 mΩ = 121 mΩ | 120 mΩ | dR31 dyn corr % = 0.8% | |

However, when the static imbalance (b) and (c) is calculated, it shows even a greater values of R stat %=4% indicating a serious problem with some copper connection (e.g. loose bolt). The ohmic static differences from (b) can be then subtracted from the raw dynamic values in (a) and thus correcting them as shown in (d). These corrected values show a much smaller corrected dynamic imbalance R dyn corr %=0.8% which would be below the threshold of 1% indicating that the dynamic fault is not as serious as the static one.

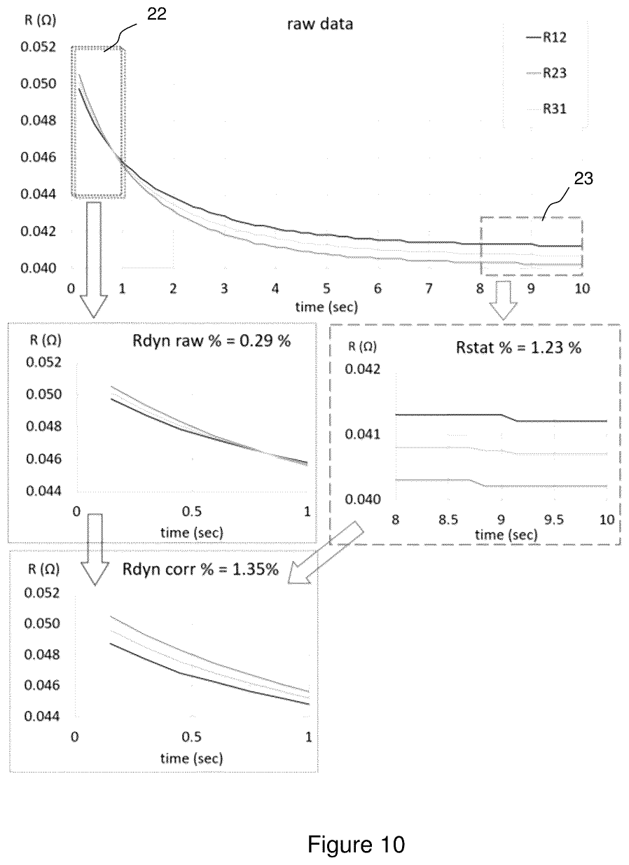

FIG. 10 is a graphical illustration of the use of static measure of impedance imbalance measured in a second time window 23 (time window A in this example) for correction of a dynamic measure of impedance imbalance measured in a first time window 22. This is an illustration of another example with two faults masking each other in the ordinary short test. As shown in FIG. 10, there are two faults masking each other if only the short Rdyn is measured (R %<0.3% means reasonably good balance), but with the presently disclosed method, both faults can be diagnosed (Rstat %>1.2% and Rdyn corr %>1.3%).

The correction can be also applied in quadrature rather than by simple subtraction, leading to similar results. The quadrature processing might be needed if the dynamic effects are excessive so that the similar idea as in the case of Z=√(R²+X²) is used. The quadrature calculation would require correction to be calculated by assuming the contribution of both factors as squares, because the assumption can be made as:

$$Rij dyn raw = √ ( Rij dyn raw {corr}^{2} + Rij {stat}^{2} ) and so :$$

$$Rij dyn raw corr = √ ( Rij dyn {raw}^{2} - Rij {stat}^{2} )$$

Therefore, squares and square roots are involved instead of simple addition and subtraction. The percentage calculations are done by a similar method to that shown in Table 1.

As shown in FIG. 8, the window length T1 of the dynamic part can be different from the window length T3 of the static part. Between them there can be a waiting time T2 of the length as dictated by the algorithm used to detect that the steady state is achieved.

Such algorithm may be based simply on the stability of readings, so if the next reading differs by a sufficiently small amount from the previous (e.g. less than 0.1%, or less than 0.1 mΩ, or some other criterion) then this may be judged as a steady state. In general, the waiting time T2 can be decided by any suitable method.

It should be noted that both dynamic and static windows could overlap, making in effect the T2 a negative value. For the example the transient state may negligibly short if the test is performed with the rotor removed. Therefore, the steady state is achieved almost immediately and thus both dynamic and static windows can have the same position (or almost the same), even right from the beginning of the trace or trajectory. Still, it is noticeable that the R23 reading is the highest which will dictate the value of the R stat %. But after applying the correction as per Table 1, the dynamic R dyn corr % will have lower value than R stat % indicating no discernible dynamic or electromagnetic problem.

The calculation algorithm as exemplified in Table 1 is an example. The actual measurements can be obtained by any suitable resistance measurement method, either by measuring the raw voltage drop, or by a bridge, or some other way. It is also possible to carry out equivalent computations based just on the voltage drop, rather than on the resistance as shown here. The result would have been equivalent.

In an example, the test may be carried out by applying a constant voltage source and the test current would be as resulting from the impedance/resistance in the circuit. In that case the voltage would be fixed, but the current would be initially smaller (in the dynamic part) only later to plateau in the static part. In other examples, similar percentage information can be extracted from such a current trajectory rather than from the resistance as described above.

An additional mode of operation could be such that additional dynamic windows could be extracted, rather than just the one shown in FIG. 8, so that here could be additional windows somewhere in the time T2, so that information could be extracted about the phase which decays more quickly or more slowly than the others. So a third value of imbalance could be calculated, and so on.

In an example, a whole trace of imbalance could be calculated, so that a full % trajectory of imbalance could be plotted on a display. It is then possible to measure the time needed for the % trajectory to cross a threshold, and the time needed to cross it can be used for diagnosis of additional fault(s).

In an example, a part of the test may be applied multiple times. For a machine for which the dynamic part is short (quick decay) it might be impossible to acquire accurate data in a short window, especially if the noise is present. For example, the dynamic part may be extremely short and the noise in the readings is comparable to the whole transient activity. The dynamic test may be repeated several times, so that the decay window can be sampled several times over the same short time interval, so that the data can be averaged over several attempts. This will enable higher accuracy of measurement to be achieved of the dynamic phenomena. During such measurement, it may be required to reach the steady state only in one of the sub-tests, because the true DC values will not change between the tests, and once they are measured the repetition can focus only on the dynamic interval, so the test current can be applied only for the duration of the short dynamic window, and repeated as necessary to reach the accurate average dynamic values. Further filtering such as median can be applied when such averaging is performed. Such filtering/averaging will be important in noisy environments, for example when testing through longer cables which are laid in the vicinity of other energised cables, which could inject noise into the measured object.

The electrical machine which is the test subject may be, in examples, a motor, generator or a transformer with at least 3 terminals, intended normally for 3-phase operation. However, the method would be suitable also for a 2-phase or 1-phase machine if at least 3 terminals are provided, but then the calculations may be carried out differently, because the 3 readings would not be equal. For example, with just 2 equal windings connected to a mutual ground point G, on the readings G-1 and G-2 can be compared, because 1-2 will produce a different value being the sum of the two. So if the calculations as per Table 1 are to be carried out they have to be adjusted accordingly (just for the two equal phases).

Returning to FIG. 6, dynamic part in time period T1 is mostly dictated by the current that is induced in the rotor due to the step-change of the current applied to the stator. The step-change induces relatively large voltage which induces relatively large instantaneous current in the rotor. This is dictated by the Faraday's law of induction in which the voltage is induced proportionally to the changes of magnetic field.

Therefore, as the stator current achieves steady-state (essentially DC) then there are no longer any changes to the current, and no changes to the magnetic field, and therefore there is no longer any current flowing in the rotor. In other words, the dynamic part during the T1 window is strongly driven by the current flowing in the rotor, and it decays to a steady state when the rotor current decays away to zero. It is expected that the time constant is dictated by the rotor time constant tr=Lr/Rr, and with extremely low values of Rr for the rotor (perhaps even as low as mΩ for large machines) even a rather small inductance Lr can result with a time constant tr which lasts for several seconds.

But, if the next trajectory (e.g. for phases 2-3), i.e. the test of the next conductive path, were started immediately after the test current for the previous conductive path was stopped, then the measurement would have been affected by the current in the rotor which was still flowing. This would potentially create a significant difference in the recorded trajectory, and thus report a dynamic imbalance for a motor in which there is none if the measurements are performed correctly.

Therefore, after switching off the current the procedure should wait for a sufficiently long time, e.g. similar to times T1+T2, so that any rotor currents can be assumed to be negligibly small so that they will not affect the dynamic part.

During such waiting time the signal across the windings can be additionally recorded, and this can be used to produce a further value of imbalance, as caused by the currents pre-dominantly in the rotor. This offers further diagnostics capability as to the location and type of the fault contributing to the dynamic imbalance, because the static part is effectively eliminated because the test current is not flowing.

The waiting time could be fixed e.g. to 30 sec, but this would make the tests unnecessary long for smaller motor which have proportionally smaller time constant. The waiting time before moving to the test of the next conduction path may be made dependent on a measurement to determine that the voltage across the stator has decayed to a threshold value.

As disclosed above, the meter may be caused by the processor to operate automatically to perform the following method: for each of a plurality of conduction paths, each comprising one or more of the plurality of windings, performing a first measurement of impedance in a given time window, for example time window B, and performing a second measurement of impedance in a further time window, for example time window A, which is different from the given time window; performing a correction of the first measurement for each conduction path using the second measurement for the respective conduction path; and determining a first measure of impedance imbalance, the first measure of impedance imbalance being of the corrected first measurements for the plurality of conduction paths and determining a second measure of impedance imbalance, the second measure of impedance imbalance being of the second measurements for the plurality of conduction paths.

The first measure of impedance imbalance may be a dynamic measure of impedance imbalance and the second measure of impedance balance may be a static measure of impedance imbalance. The processor may process the measurement results to generate an indication of a first type of fault in the electrical machine dependent on a determination that the dynamic measure of impedance imbalance exceeds a threshold. The first type of fault may comprise a fault in an electromagnetic component of the machine. The processor may process the measurement results to generate an indication of a second type of fault in the electrical machine dependent on a determination that the static measure of impedance imbalance exceeds a threshold. The second type of fault may comprise a fault causing a change in resistance. The threshold may be passed if a measure of dynamic or static impedance imbalance exceeds the threshold. For example, if the static or dynamic impedance for a given conduction path differs for the mean impedance for the conduction paths by more than a given percentage, for example 1%, a fault may be declared. The processor may generate an indication of the fault, for example an electronic signal. An indication of the fault may be displayed on the meter, or relayed to a further data logging or display device.

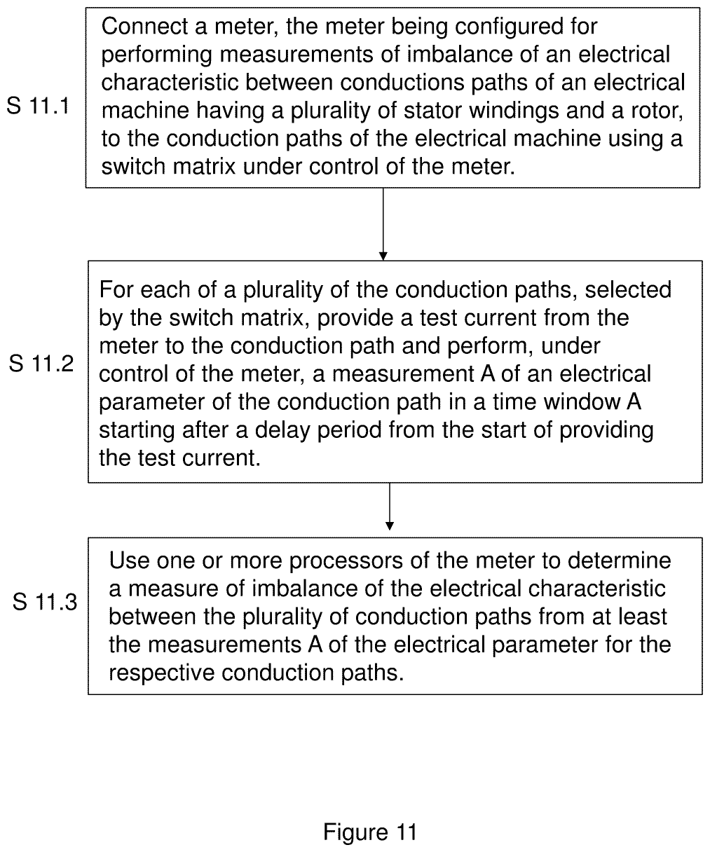

FIG. 11 is a flow diagram of a method of operation of a meter according to this disclosure. Step S11.1 is to connect a meter, the meter being configured for performing measurements of imbalance of an electrical characteristic between conductions paths of an electrical machine having a plurality of stator windings and a rotor, to the conduction paths of the electrical machine using a switch matrix under control of the meter. Step S11.2 is, for each of a plurality of the conduction paths, selected by the switch matrix, to provide a test current from the meter to the conduction path and perform, under control of the meter, a measurement A of an electrical parameter of the conduction path in a time window A starting after a delay period from the start of providing the test current. Step S11.3 is to use one or more processors of the meter to determine a measure of imbalance of the electrical characteristic between the plurality of conduction paths from at least the measurements A of the electrical parameter for the respective conduction paths.

The following examples A to T are provided as examples of features described in this disclosure.

Example A. A method performed by a meter for performing measurements of imbalance of an electrical characteristic between conduction paths of an electrical machine having a plurality of stator windings and a rotor, the method comprising, with the rotor in place in the electrical machine:
for each of a plurality of conduction paths, each comprising one or more of the plurality of stator windings, providing a test current to the conduction path and performing a measurement A of an electrical parameter of the conduction path in a time window A starting after a delay period from the start of providing the test current; and
determining a measure of imbalance of the electrical characteristic between the plurality of conduction paths from at least the measurements A of the electrical parameter for the respective conduction paths.

Example B. A method according to example A, wherein the delay period is at least as long as the time window A.

Example C. A method according to Example A or Example B, wherein the delay period is sufficient to allow the electrical parameter of the conduction path to settle to within 10% or less of a steady state value.

Example D. A method according to any preceding Example, comprising providing the test current to the conduction path for at least the delay period and the time window A

Example E. A method according to Example D, wherein said electrical characteristic is impedance, the method comprising:
for each of the plurality of conduction paths, performing a measurement B of the electrical parameter of the conduction path in a time window B which starts before the time window A;
calculating a measure A of the impedance for each conduction path from the measurement A of the electrical parameter;
calculating a measure B of the impedance for each conduction path from the measurement B of the electrical parameter;
performing a correction of the measure B of the impedance for each conduction path using the measure A of the impedance for the respective conduction path; and
determining a dynamic measure of impedance imbalance, the dynamic measure of impedance imbalance being the imbalance of the corrected measures B for the plurality of conduction paths and determining a static measure of impedance imbalance, the static measure of impedance imbalance being the imbalance of the measures A for the plurality of conduction paths.

Example F. A method according to Example E, wherein performing the correction of the measure B for each conduction path comprises subtracting the difference between measure A and the mean of measures A for the plurality of conduction paths from measure B for the respective conduction path.

Example G. A method according to Example E, wherein performing the correction of the measure B for each conduction path comprises quadrature processing of the measure B and the measure A for the respective conduction path.

Example H. A method according to claim any one of Examples E-G, wherein the time window A for each of the plurality of conduction paths occurs after a waiting time after the end of the time window B.

Example I. A method according to any one of Examples E-H, comprising performing the measurement B of the electrical parameter a plurality of times for each of the plurality of conduction paths and determining a plurality of dynamic measures of impedance imbalance from the measurements B.

Example J. A method according to Example I, comprising:
determining a measure of the variation of the plurality of the dynamic measures of impedance imbalance; and
performing further measurements B dependent on the measure of the variation exceeding or equalling a threshold.

Example K. A method of any one of Examples E-J, comprising generating an indication of a first type of fault in the electrical machine dependent on a determination that the dynamic measure of impedance imbalance exceeds a threshold.

Example L. A method according to Example K, wherein the first type of fault comprises a fault in an electromagnetic component of the machine.

Example M. A method of any one of Examples E-L, comprising generating an indication of a second type of fault in the electrical machine dependent on a determination that the static measure of impedance imbalance exceeds a threshold.

Example N. A method according to Example M, wherein the second type of fault comprises a fault causing a change in resistance.

Example O. A method according to any one of Examples E-O, comprising stopping providing the test current after the time window A, and
for each of the plurality of conduction paths, performing a measurement C of an electrical parameter across the conduction path in a time window C starting after stopping providing the test current; and
determining a measure of imbalance of induced voltage characteristics between the plurality of conduction paths from at least the measurements C of the electrical parameter for the respective conduction paths.

Example P. A method according to any one of Examples A-C comprising stopping providing the test current before the time window A.

Example Q. A method according to Example P, wherein the electrical characteristic is an induced voltage characteristic.

Example R. A method according to Example Q, comprising generating an indication of a fault in an electromagnetic component in the electrical machine dependent on a determination that the imbalance of induced voltage characteristics exceeds a threshold.

Example S. A meter for performing measurements of imbalance of an electrical characteristic between conduction paths of an electrical machine having a plurality of stator windings and a rotor with the rotor in place in the electrical machine, the meter comprising a current generation circuit, an electrical parameter measurement circuit, one or more processors and memory holding computer-readable instructions configured to cause the one or more processors to cause the meter to perform a method comprising:
for each of a plurality of conduction paths, each comprising one or more of the plurality of stator windings providing a test current to the conduction path and performing a measurement A of an electrical parameter of the conduction path in a time window A starting after a delay period from the start of providing the test current; and
determining a measure of imbalance of the electrical characteristic between the plurality of conduction paths from at least the measurements A of the electrical parameter for the respective conduction paths.

Example T. A meter according to Example S, comprising a switch matrix configured, under control of the one or more processors of the meter, to connect a current generation circuit and an electrical parameter measurement circuit to each of a plurality of windings of the electrical machine in turn for tests of the respective winding.

The above embodiments are to be understood as illustrative examples of the invention. It is to be understood that any feature described in relation to any one embodiment may be used alone, or in combination with other features described, and may also be used in combination with one or more features of any other of the embodiments, or any combination of any other of the embodiments. Furthermore, equivalents and modifications not described above may also be employed without departing from the scope of the invention, which is defined in the accompanying claims.

What we claim is:

1. A method performed by a meter for performing measurements of imbalance of an electrical characteristic between conduction paths of an electrical machine having a plurality of stator windings and a rotor, the method comprising, with the rotor in place in the electrical machine:
for each of a plurality of conduction paths, each comprising one or more of the plurality of stator windings, providing a test current to the conduction path and performing a measurement A of an electrical parameter of the conduction path in a time window A starting after a delay period from the start of providing the test current; and
determining a measure of imbalance of the electrical characteristic between the plurality of conduction paths from at least the measurements A of the electrical parameter for the respective conduction paths.

2. The method of claim 1, wherein the delay period is at least as long as the time window A.

3. The method of claim 1, wherein the delay period is sufficient to allow the electrical parameter of the conduction path to settle to within 10% or less of a steady state value.

4. The method of claim 1, comprising providing the test current to the conduction path for at least the delay period and the time window A.

5. The method of claim 4, wherein said electrical characteristic is impedance, the method comprising:
for each of the plurality of conduction paths, performing a measurement B of the electrical parameter of the conduction path in a time window B which starts before the time window A;
calculating a measure A of the impedance for each conduction path from the measurement A of the electrical parameter;
calculating a measure B of the impedance for each conduction path from the measurement B of the electrical parameter;
performing a correction of the measure B of the impedance for each conduction path using the measure A of the impedance for the respective conduction path; and
determining a dynamic measure of impedance imbalance, the dynamic measure of impedance imbalance being the imbalance of the corrected measures B for the plurality of conduction paths and determining a static measure of impedance imbalance, the static measure of impedance imbalance being the imbalance of the measures A for the plurality of conduction paths.

6. The method of claim 5, wherein performing the correction of the measure B for each conduction path comprises subtracting the difference between measure A and the mean of measures A for the plurality of conduction paths from measure B for the respective conduction path.

7. The method of claim 5, wherein performing the correction of the measure B for each conduction path comprises quadrature processing of the measure B and the measure A for the respective conduction path.

8. The method of claim 5, wherein the time window A for each of the plurality of conduction paths occurs after a waiting time after the end of the time window B.

9. The method of claim 5, comprising performing the measurement B of the electrical parameter a plurality of times for each of the plurality of conduction paths and determining a plurality of dynamic measures of impedance imbalance from the measurements B.

10. The method of claim 9, comprising:
determining a measure of the variation of the plurality of the dynamic measures of impedance imbalance; and
performing further measurements B dependent on the measure of the variation exceeding or equalling a threshold.

11. The method of claim 5, comprising generating an indication of a first type of fault in the electrical machine dependent on a determination that the dynamic measure of impedance imbalance exceeds a threshold.

12. The method of claim 11, wherein the first type of fault comprises a fault in an electromagnetic component of the machine.

13. The method of claim 5 comprising generating an indication of a second type of fault in the electrical machine dependent on a determination that the static measure of impedance imbalance exceeds a threshold.

14. The method of claim 13, wherein the second type of fault comprises a fault causing a change in resistance.

15. The method of claim 5, comprising stopping providing the test current after the time window A, and
for each of the plurality of conduction paths, performing a measurement C of an electrical parameter across the conduction path in a time window C starting after stopping providing the test current; and
determining a measure of imbalance of induced voltage characteristics between the plurality of conduction paths from at least the measurements C of the electrical parameter for the respective conduction paths.

16. The method of claim 1 comprising stopping providing the test current before the time window A.

17. The method of claim 16, wherein the electrical characteristic is an induced voltage characteristic.

18. The method of claim 17, comprising generating an indication of a fault in an electromagnetic component in the electrical machine dependent on a determination that the imbalance of induced voltage characteristics exceeds a threshold.

19. A meter for performing measurements of imbalance of an electrical characteristic between conduction paths of an electrical machine having a plurality of stator windings and a rotor with the rotor in place in the electrical machine, the meter comprising a current generation circuit, an electrical parameter measurement circuit, one or more processors and memory holding computer-readable instructions configured to cause the one or more processors to cause the meter to perform a method comprising:
for each of a plurality of conduction paths, each comprising one or more of the plurality of stator windings providing a test current to the conduction path and performing a measurement A of an electrical parameter of the conduction path in a time window A starting after a delay period from the start of providing the test current; and
determining a measure of imbalance of the electrical characteristic between the plurality of conduction paths from at least the measurements A of the electrical parameter for the respective conduction paths.

20. The meter of claim 19, comprising a switch matrix configured, under control of the one or more processors of the meter, to connect a current generation circuit and an electrical parameter measurement circuit to each of a plurality of windings of the electrical machine in turn for tests of the respective winding.
